(19) United States
(12) Patent Application Publication
(10) Pub. No.: US 2021/0109451 A1
(43) Pub. Date: Apr. 15, 2021

(54) SPIN-ON METAL OXIDE MATERIALS OF HIGH ETCH RESISTANCE USEFUL IN IMAGE REVERSAL TECHNIQUE AND RELATED SEMICONDUCTOR MANUFACTURING PROCESSES

(71) Applicant: Merck Patent GmbH, Darmstadt (DE)

(72) Inventor: Huirong YAO, Plainsboro, NJ (US)

(21) Appl. No.: 17/021,203

(22) Filed: Sep. 15, 2020

Related U.S. Application Data
(60) Provisional application No. 62/913,807, filed on Oct. 11, 2019.

(51) Int. Cl. G03F 7/40; G03F 7/16; G03F 7/11

(52) U.S. Cl. CPC G03F 7/405; G03F 7/11; G03F 7/16; G03F 7/40

(57) ABSTRACT

The disclosed and claimed subject matter relates hybrid metallic oxide formulations useful for filling trenches and vias during lithographic processes (e.g., image reversal) that include (i) one or more metal salts, (ii) an organic polymer and (iii) one or more solvents.

### BACKGROUND

### Field

The disclosed subject matter relates to formulations and their use that are soluble in organic solvent and/or aqueous solvent to obtain spin-on coated materials with excellent moisture resistance and high metal content. In particular, the formulations are hybrid metallic oxide formulations useful for filling trenches and vias during lithographic processes (e.g., image reversal) that include (i) one or more metal salts, (ii) an organic polymer and (iii) one or more solvents.

### Related Art

Photoresist compositions are used in microlithography processes for fabricating miniaturized electronic components such as computer chips and integrated circuits. Lithography processes generally involve application of a thin coating (i.e., a film) of a photoresist composition to a substrate (e.g., silicon wafers used for making integrated circuits). The coated substrate is then baked to evaporate any solvent in the photoresist composition and to “fix” the coating to the substrate. The photoresist coated on the substrate is next subjected to an image-wise exposure to actinic radiation. Various types of actinic radiation are commonly used in microlithographic processes, including visible light, ultraviolet (UV) light, extreme ultraviolet (EUV) light, electron beam and X-ray radiant energy.

Exposure to the actinic radiation causes a chemical transformation in the exposed areas of the coated surface. After the exposure, the coated substrate is treated with a developer solution to dissolve and remove either the radiation-exposed areas (for positive-type photoresists) or the unexposed areas (for negative-type photoresists) of the coated surface of the substrate.

After the forgoing development operation, the now partially unprotected substrate may be treated with a substrate-etchant solution, plasma gases or reactive ions, or have metal/metal composites deposited in the spaces of the substrate where the photoresist coating was removed during development. The areas of the substrate where the photoresist coating is not removed remains protected. Later, the remaining areas of the photoresist coating may be removed during a stripping operation, leaving a patterned substrate surface. In some instances, it is desirable to heat treat the remaining photoresist layer, after the development step and before the etching step, to increase its adhesion to the underlying substrate.

Silicon oxide films have been used extensively as masks of photoresist. The silicon oxide films can be easily formed by casting and then heating silicon-containing compositions that are coated on a wafer/substrate. Such silicon-containing compositions include, for example, polysilazane, polysiloxane or the like.

Other metal oxide films have also been utilized as used as photoresist masks, such as tungsten oxide and titanium oxide. For example, tungsten oxide films have been used owing to their relatively low volume shrinkage ratio. They therefore do not suffer as many defects, such as voids. In addition, they can be readily and easily removed with water. Thus, in some ways tungsten oxide films often exhibit properties more advantageous than the silicon oxide ones. However, tungsten oxide films are difficult to prepare by way of traditional casting compositions that can be readily spin coated on a wafer/substrate; instead they must be applied by vapor deposition methods which limits their usefulness on a production scale.

Resist, including those derived from metal oxides, can be used in image reversal processes. In such processes a positive photoresist is utilized in a manner such that it effectively functions as a negative resist (i.e., the positive resist is “reversed”). In a typical procedure using a positive resist, the portions of the resist layer exposed to UV radiation are made susceptible to remover by a developer while the unexposed regions (i.e., those that were “masked” from the UV exposure) remain. An image reversal process changes this typical outcome.

In one image reversal method, a crosslinkable positive resist is utilized (e.g., a Novolac-based resist). After an initial UV exposure using an inverted mask, crosslinking is induced (e.g., by the use of ammonia or a baking step) which results in the exposed region(s) becoming inert while the unexposed regions remain photoactive. Thereafter, the entire resist layer is exposed without a mask (i.e., is flood exposed). This exposure renders the previously unexposed regions susceptible to removal with a developer while the initially UV exposed region is not susceptible to removal because the crosslinking step rendered it insoluble in the developer.

In another method that does not necessarily require the use of a crosslinkable resist, the resist pattern formed is filled and overcoated with a metal oxide composition after UV exposure and developing. The “overcoat” portion is then removed (e.g., by etching, mechanical polishing/planarization or other known techniques) to be level with the resist such that the surface of the remaining resist is exposed. The resist is then removed by known etching procedures to produce trenches (where the metal oxide composition wholly or partially defines the side wall of the trench). The above-described metal oxide films have been used in this type of image reversal technique. In such applications, however, the above materials exhibit unacceptably poor etch resistance. As noted above, they also suffer from limited solvent solubility that compromises their ability to applied.

In view of the above, there is a need for photoresist materials that exhibit good solubility in organic solvent and/or aqueous solvents to obtain spin-on coated materials with excellent moisture resistance and high metal content (e.g., greater than 40% by weight) that can be used in image reversal processes.

### SUMMARY

In one aspect, the disclosed subject matter relates to hybrid metallic oxide formulations useful for filling trenches and vias during image reversal lithographic processes that include (i) one or more metal salts, (ii) an organic polymer and (iii) one or more solvents. In a further embodiment, the hybrid metallic oxide formulations consist essentially of (i) one or more metal salts, (ii) an organic polymer and (iii) one or more solvents. In such an embodiment, the combined amounts of (i) one or more metal salts, (ii) an organic polymer and (iii) one or more solvents do not equal 100% by weight, and can include other ingredients (e.g., common additives and/or impurities) that do not materially change the effectiveness of the metallic oxide formulations. In yet another embodiment, the metallic oxide formulations consist of (i) one or more metal salts, (ii) an organic polymer and (iii) one or more solvents. In such an embodiment, the combined amounts of (i) one or more metal salts, (ii) an organic polymer and (iii) one or more solvents equal approximately 100% by weight but may include other small and/or trace amounts of impurities that are present in such small quantities that they do not materially change the effectiveness of the hybrid metallic oxide formulations. For example, in one such embodiment, the hybrid metallic oxide formulations can contain 2% by weight or less of impurities. In another embodiment, the hybrid metallic oxide formulations can contain 1% by weight or less than of impurities. In a further embodiment, the hybrid metallic oxide formulations can contain 0.05% by weight or less than of impurities. Notably, the disclosed hybrid solution of a metal salt and the organic polymer will not dissolve an underlying material on which it is applied, such as a pattern photoresist.

In another aspect, the metal salt of the hybrid metallic oxide formulations includes one or more of Ti(IV), Zr(IV), Hf(IV), Mo(VI), Sn(IV), Al(III), In(III), Ga(III) and Zn(II). In yet a further aspect, the metal is zirconium.

In another aspect, the metal salts of the hybrid metallic oxide formulations include any acceptable counterion(s), including, but not limited to one or more of a nitrate, a sulfate, an acetate, a fluorinated alkylacetate, a fluorinated alkysulfonate, a (meth)acrylates and combinations thereof. In another aspect, the counterion is a nitrate. In yet another aspect, the counterion is a methacylate. In yet another aspect, the counterion is a sulfate. In yet another aspect, the counterion is an acetate.

In another aspect, suitable metal salts for use in the hybrid metallic oxide formulations include, but are not limited to, zirconyl nitrate, aluminum nitrate, zirconyl methacylate, aluminum sulfate, titanium oxysulfate, aluminum trifluoroacetate and aluminum trifluorosulfonate.

In another aspect, the hybrid metallic oxide formulations include one or more optional additives including, but not limited to catalysts, crosslinkers, photoacid generators, organic polymers, inorganic polymers, surfactants, stabilizers, wetting agents, anti-foam agents, thixotropic agents and combinations thereof.

In another aspect, the hybrid metallic oxide formulations are soluble in an organic solvent, an aqueous solvent (e.g., water) or a combination thereof. In a further aspect, the solvent is one or more of water, an alcohol, an ester, an alkylcarboxylic acid, a ketone, a lactone, a diketone, or a combination thereof. In yet a further aspect, the solvent is water, a cyclohexanone, a propylene glycol monomethyl ether acetate (PGMEA), a propylene glycol monomethyl ether (PGME) or a combination thereof.

In another aspect, the hybrid metallic oxide formulations are and/or include the metallic oxide formulations and compositions disclosed in U.S. Pat. No. 10,241,409, the contents of which are incorporated herein in their entirety.

In another aspect, the hybrid metallic oxide formulations have an organic content that is no more than approximately 40%. In another aspect, the hybrid metallic oxide formulations have an organic content that is no more than approximately 40%. In another aspect, the hybrid metallic oxide formulations have an organic content that is no more than approximately 20%. In a further aspect, the hybrid metallic oxide formulations have an organic content that is no more than approximately 10%. In yet a further aspect, the hybrid metallic oxide formulations have an organic content that is no more than approximately 5%.

In another aspect, the hybrid metallic oxide formulations have a total solids content ranging from 2% by weight and approximately 30% by weight. In some embodiments, the solids content is adjusted to approximately 5% by weight to approximately 20% by weight before being applied to a wafer/substrate.

In another aspect, the disclosed subject matter relates to a process for using the hybrid metallic oxide formulations for coating a substrate where the hybrid metallic oxide formulations are applied on the substrate and the coated substrate is heated to form a metal oxide layer. In a further aspect, the metal oxide layer has a metal oxide content of between approximately 20% by weight to approximately 60% by weight. In another aspect, the produced metal oxide layer has a metal oxide content of between approximately 30% by weight to approximately 50% by weight. In another embodiment, the produced metal oxide layer has a metal oxide content of at least approximately 20% by weight. In another embodiment, the produced metal oxide layer has a metal oxide content of at least approximately 30% by weight. In another embodiment, the produced metal oxide layer has a metal oxide content of at least approximately 40% by weight. In another embodiment, the produced metal oxide layer has a metal oxide content of at least approximately 50% by weight. In another embodiment, the produced metal oxide layer has a metal oxide content of at least approximately 60% by weight.

In another aspect, the process for producing the metal oxide layer using the hybrid metallic oxide formulations includes performing an image reversal process to reverse a lithographic image/feature (e.g., convert lines to trenches or contact holes to pillars etc.). In a further aspect, the image reversal process utilizing the hybrid metallic oxide formulations includes (i) coating/filling trenches and/or vias in a wafer/substrate with the hybrid metallic oxide formulations, (ii) removing the overcoating of the photoresist features (e.g., etching with a plasma (such as a fluorine-based plasma etch), etching with a chemical solution or chemical mechanical polishing) and (iii) removing the original photoresist (e.g., with an appropriate plasma, such as an oxygen plasma) while the metal oxide material remains in the filled areas and forms an image tone reversal. This process is described in more detail below. In such a process, the metal oxide layer serves as a hardmask for further pattern transfer which can be used in a dry development rinse (DDR) process and/or as a material for collapse free technique on the order of 20 or less nm half pitch and beyond.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates a substrate 10 with a resist 20 having been disposed thereon;

FIG. 2. illustrates the formation of a photoresist pattern on substrate 10 as a result of masking, UV exposing and developing resist 20 (such that the masked areas remain);

FIG. 3 illustrates the overcoating of the photoresist pattern with the disclosed metallic oxide formulations to form metallic oxide layer 30; and

FIG. 4 illustrates the removal of at least a portion of the overcoated portion (i.e., the portion extending above resist 20) of metallic oxide layer 30 such that the metallic oxide layer has a thickness approximately equal to the thickness of resist 20 and so that the top surface of resist 20 is exposed; and

FIG. 5 illustrates the formation of a reverse tone pattern as a result of a further etching to remove resist 20 thereby leaving trench 40 in substrate 10.

### DEFINITIONS

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including,” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

As used herein, “C_{x-y}” designates the number of carbon atoms in a chain. For example, C₁₋₆ alkyl refers to an alkyl chain having a chain of between 1 and 6 carbons (e.g., methyl, ethyl, propyl, butyl, pentyl and hexyl). Unless specifically stated otherwise, the chain can be linear or branched.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). These alkyl moieties may be substituted or unsubstituted.

“Halogenated alkyl” refers to a linear, cyclic or branched saturated alkyl group as defined above in which one or more of the hydrogens has been replaced by a halogen (e.g., F, Cl, Br and I). Thus, for example, a fluorinated alkyl (a.k.a. “fluoroalkyl”) refers to a linear, cyclic or branched saturated alkyl group as defined above in which one or more of the hydrogens has been replaced by fluorine (e.g., trifluoromethyl, pefluoroethyl, 2,2,2-trifluoroethyl, prefluoroisopropyl, perfluorocyclohexyl and the like). Such haloalkyl moieties (e.g., fluoroalkyl moieties), if not perhalogenated/multihalogentated, may be unsubstituted or further substituted.

“Alkoxy” (a.k.a. “alkyloxy”) refers to an alkyl group as defined above which is attached through an oxy (—O—) moiety (e.g., methoxy, ethoxy, propoxy, butoxy, 1,2-isopropoxy, cyclopentyloxy, cyclohexyloxy and the like). These alkoxy moieties may be substituted or unsubstituted.

“Alkyl carbonyl” refers to an alkyl group as defined above which is attached through a carbonyl group (—C(═O)) moiety (e.g., methylcarbonyl, ethylcarbonyl, propylcarbonyl, buttylcarbonyl, cyclopentylcarbonyl and the like). These alkyl carbonyl moieties may be substituted or unsubstituted.

“Halo” or “halide” refers to a halogen (e.g., F, Cl, Br and I).

“Hydroxy” (a.k.a. “hydroxyl”) refers to an —OH group.

Unless otherwise indicated, the term “substituted” when referring to an alkyl, alkoxy, fluorinated alkyl and the like refers to one of these moieties which also contains one or more substituents including, but not limited, to the following substituents: alkyl, substituted alkyl, unsubstituted aryl, substituted aryl, alkyloxy, alkylaryl, haloalkyl, halide, hydroxy, amino and amino alkyl. Similarly, the term “unsubstituted” refers to these same moieties where no substituents apart from hydrogen are present.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

As set forth above, the disclosed subject matter relates to metallic oxide formulations useful for filling trenches and vias during lithographic processes. Among other things, the metallic oxide formulations can be used for image reversal in such processes. The metallic oxide formulations generally include (i) one or more metal salts, (ii) an organic polymer and (iii) one or more solvents. The metallic oxide formulations can further include one or more optional ingredients. The metallic oxide formulations suitable for use in the image reversal processes can include, for example, those disclosed and claimed in U.S. Pat. No. 10,241,409 which are directed to compositions that include a metal salt solution, a stabilizer and one or more optional ingredient.

Metal Salt

The metallic oxide formulations can include one or more metal salts. Such metal salts can be readily obtained, for example from commercial sources, and include any one or more of the following metal ions: Ti(IV), Zr(IV), Hf(IV), W(VI), Mo(VI), Sn(IV), Al(III), In(III), Ga(III) and Zn(II). The metal salts can include any counterions, including, but not limited to nitrate, sulfate, acetate, fluorinated alkylacetate, fluorinated alkysulfonate and (meth)acrylate. Examples of suitable metal salts for use in the metallic oxide formulations include, but are not limited to, zirconyl nitrate, aluminum nitrate, zirconyl methacylate, aluminum sulfate, titanium oxysulfate, aluminum trifluoroacetate and aluminum trifluorosulfonate. More than one metal/metal salt may be included in the metallic oxide formulations depending on the desired properties of the final crosslinked layer. For example, zirconium and titanium may be combined to give a layer with very good etch resistance, thermal conductivity and high refractive index.

The metallic oxide formulations generally include at least approximately 50% by weight of the metal salts. In other embodiments, the metallic oxide formulations include greater than approximately 70% by weight of the metal salts. Those skilled in the art will recognize that metallic oxide formulations having below approximately 50% by weight of the metal salts may not be as effective for use as gap filling compositions compared to metallic oxide formulations with approximately 50% by weight or more of the metal salts. However, to the extent that a particular lithographic process is amenable to or otherwise requires the use of lower weight percentages of the metal salts, the disclosed metallic oxide formulations can include below approximately 50% by weight of the metal salts.

Those skilled in the art will further recognize that metallic oxide formulations including “at least approximately 50% by weight of the metal salts” is not a strictly bounded threshold and includes amounts of the metal salts somewhat below 50% by weight. In one embodiment, for example, a metallic oxide formulation that includes “at least approximately 50% by weight of the metal salts” can include 10% less than the weight percent of the metal salts. Thus, in such an embodiment of the metallic oxide formulation including “at least approximately 50% by weight of the metal salts” can include 45% by weight of the metal salts. In another embodiment, for example, a metallic oxide formulation that includes “at least approximately 50% by weight of the metal salts” can include 5% less than the weight percent of the metal salts. Thus, in such an embodiment of the rinse including “at least approximately 50% by weight of the metal salts” can include 47.5% by weight of the metal salts.

Organic Polymer(s)

The use of an appropriate organic polymers is a must for good filling performance on a patterned underlying structure. The organic polymer should contain crosslinkable groups (e.g., epoxies, hydroxyls, thiols, amines, amides, imides, esters, ethers, ureas, carboxylic acids, anhydrides, glycidyl ether groups, glycidyl ester groups, glycidyl amino groups, methoxymethyl groups, ethoxy methyl groups, benzyloxymethyl groups, dimethylamino methyl groups, diethylamino methyl groups, dimethylol amino methyl groups, diethylol amino methyl groups, morpholino methyl groups, acetoxymethyl groups, benzyloxy methyl groups, formyl groups, acetyl groups, vinyl groups and isopropenyl groups). The polymers can also be otherwise substituted with other substituents such as fluoroalkyl or fluoroalcohol groups. In addition, the polymers for use in the disclosed metallic oxide formulations are preferably soluble in aqueous or alcohol solutions (as are described below). Polymers such as film forming organic or organo-silicon polymers can be used, such as, for example, polyacrylics, polymethacrylates, and condensation polymers such as polyesters, novolac resins, or organosilsesquioxanes. These polymers may be used alone or in combination with each other, depending on the desired properties of the final film after curing. Examples of particularly suitable polymers include, but are not limited to, polyvinylalcohol, polyvinylpyrridone, polyethyleneglycol, polypropyleneglycol and condensation polymers, such as polyester and novolac resin.

The metallic oxide formulations generally include no more than approximately 40% by weight of the organic polymer(s). In some embodiments, it is preferable that the amount of organic polymer does not exceed approximately 20% by weight in the metallic oxide formulations. Notwithstanding the forgoing, those skilled in the art will recognize that use of quantities of the polymer exceeding approximately 40% by weight will generally have a deleterious effect on the usefulness of the disclosed formulations as gap filling compositions. However, to the extent that a particular lithographic process is amenable to use of the disclosed formulations having higher weight percentages of the polymer, the disclosed formulations can include in excess of 40% by weight of the polymer.

In this regard, those skilled in the art will further recognize that metallic oxide formulations including “no more than approximately 40% by weight of the organic polymer(s)” is not a strictly bounded threshold and includes amounts of the metal salts somewhat exceeding 40% by weight. In one embodiment, for example, a metallic oxide formulation that includes “no more than approximately 40% by weight of the organic polymer(s)” can include 10% above that weight percent of the organic polymer(s). Thus, in such an embodiment of the metallic oxide formulation including “no more than approximately 40% by weight of the organic polymer(s)” can include 44% by weight of the organic polymer(s). In another embodiment, for example, a metallic oxide formulation that includes “no more than approximately 40% by weight of the organic polymer(s)” can include 5% above that weight percent of the organic polymer(s). Thus, in such an embodiment of the rinse including “no more than approximately 40% by weight of the organic polymer(s)” can include 42% by weight of the organic polymer(s).

Solvent(s)

One or more solvents, including aqueous solvents, can be used in the metallic oxide formulations. In particular, the solvent can be (i) water alone, (ii) an aqueous solvent system that includes water and an organic solvent or (iii) an organic solvent. Examples of such solvents include, but are not limited to, water, an alcohol, an ester, an ether, an alkylcarboxylic acid, a ketone, a lactone, a diketone, or a combination thereof. More specifically, suitable solvents include, but are not limited to, ethylene glycol monoalkyl ethers, diethylene glycol dialkyl ethers, propylene glycol monoalkyl ethers, propylene glycol dialkyl ethers, acetate esters, hydroxyacetate esters, lactate esters, ethylene glycol monoalkylether acetates, propylene glycol monoalkylether acetates, alkoxyacetate esters, cyclic ketones, non-cyclic ketones, acetoacetate esters, pyruvate esters and propionate esters. Suitable organic solvents include, but are not limited to, cyclohexanone, a propylene glycol monomethyl ether acetate (PGMEA), propylene glycol monomethyl ether (PGME) or a combination thereof. The solvent can also include at least one high boiling point solvent, such as benzylethyl ether, dihexyl ether, diethylene glycol monomethyl ether, diethylene glycol monoethyl ether, acetonylacetone, caproic acid, capric acid, 1-octanol, 1-nonanol, benzyl alcohol, benzyl acetate, ethyl benzoate, diethyl oxalate, diethyl maleate, γ-butyrolactone, ethylene carbonate, propylene carbonate and phenylcellosolve acetate.

The one or more solvents can also include an additional cosolvent, presolvent or solvent additives that help improve formulation stability or coating performances. Examples of such include, but are not limited to, esters, alkylcarboxylic acids, ketones, lactones, diketones and combinations thereof.

In another of aspect, the disclosed subject relates to a process for making the disclosed metallic oxide formulations that includes dissolving a metal salt is dissolved in a solvent to form a solution. In some embodiments, the metal salt is dissolved in a pre-solvent prior to dissolving the metal salt in the solvent. Suitable pre-solvents include, but are not limited to, alcohols, esters, alkylcarboxylic acids, ketones, lactones, diketones, and combinations thereof. An example pre-solvent is acetone. In some embodiments, the boiling point of the pre-solvent is lower than approximately 100° C., or lower than approximately 70° C. Those skilled in the art will further recognize that these boiling points are not strictly bounded thresholds and include temperatures outside of these approximate temperatures. In one embodiment, for example, a pre-solvent that has a boiling point exceeding approximately 100° C. can be 10% above that temperature (i.e., can be 110° C.). Similarly, a pre-solvent that has a boiling point exceeding approximately 70° C. can be 10% above that temperature (i.e., can be 77° C.). In another embodiment, for example, a pre-solvent that has a boiling point exceeding approximately 100° C. can be 5% above that temperature (i.e., can be 105° C.). Similarly, a pre-solvent that has a boiling point exceeding approximately 70° C. can be 5% above that temperature (i.e., can be 73.5° C.).

In certain variations, at least a portion of the pre-solvent, or at least approximately 95% of the pre-solvent, or at least approximately 98% of the pre-solvent, is removed. For example, at least a portion of the pre-solvent can be removed by evaporation. In particular, the evaporation can be carried out using a rotary evaporator. In certain variations, the metal salt-pre-solvent solution is filtered.

Optional Ingredients

The disclosed metallic oxide formulations can include one or more optional ingredients (i.e., additives) regularly used in the industry and as known to those skilled in the art that enhance the desired properties of the compositions and/or final coatings formed from the compositions. Those skilled in the art will recognize that the amount of each of the optional ingredient(s) can be varied in the metallic oxide formulations. These optional ingredients include, but are not limited to catalysts (e.g., thermal acid generators, peroxides, etc.), stabilizers, crosslinkers, photoacid generators, inorganic polymers, surfactants, anti-foam agents, thixotropic agents and combinations thereof.

The one or more optional additives can be present in the metallic oxide formulations at a content of no more than approximately 20% by weight. In still further embodiments, the one or more optional additives can be present in the metallic oxide formulations at a content of no more than 10%. In yet further embodiments, the one or more optional additives can be present in the metallic oxide formulations at a content of no more than approximately 5% by weight. In even further embodiments, the one or more optional additives can be present in the metallic oxide formulations at a content of no more than approximately 1% by weight. Those skilled in the art will further recognize that the above-described amounts of the one or more optional additives are not strictly bounded thresholds and include amounts of such optional ingredients outside of these weight percentages. In some embodiments, for example, the one or more optional ingredients can be present in amounts exceeding the disclosed amount by 10%. Thus, an embodiment of the metallic oxide formulations including “no more than approximately 20% by weight” of the one or more optional ingredients can include 22% by weight of the one or more optional ingredients. Similarly, embodiment of the metallic oxide formulations including “no more than approximately 10% by weight,” “no more than approximately 5% by weight” and “no more than approximately 1% by weight,” respectively, of the one or more optional ingredients can include 11% by weight, can include 5.5% by weight and can include 1.1% by weight, respectively, of the one or more optional ingredients. In some embodiments, for example, the one or more optional ingredients can be present in amounts exceeding the disclosed amount by 5%. Thus, an embodiment of the metallic oxide formulations including “no more than approximately 20% by weight” of the one or more optional ingredients can include 21% by weight of the one or more optional ingredients. Similarly, embodiments of the metallic oxide formulations including “no more than approximately 10% by weight,” “no more than approximately 5% by weight” and “no more than approximately 1% by weight,” respectively, of the one or more optional ingredients can include 10.5% by weight, can include 5.25% by weight and can include 1.05% by weight, respectively, of the one or more optional ingredients.

A. Catalysts

The metallic oxide formulations can include one or more catalysts to assist or otherwise alter film curing. Suitable catalysts include, but are not limited to, thermal acid generators, thermal base generators, peroxides and combinations thereof.

1. Thermal Acid Generators

Suitable nonionic thermal acid generators for use in the metallic oxide formulations include, for example, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids such as p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof.

Suitable ionic thermal acid generators include, for example, dodecylbenzenesulfonic acid triethylamine salts, dodecylbenzenedisulfonic acid triethylamine salts, p-toluene sulfonic acid-ammonium salts, sulfonate salts, such as carbocyclic aryl (e.g., phenyl, napthyl, anthracenyl, etc.) and heteroaryl (e.g., thienyl) sulfonate salts, aliphatic sulfonate salts and benzenesulfonate salts.

2. Thermal Base Generator

The metallic oxide formulations can also optionally include one or more thermal base generators. Suitable thermal base generators include, but are not limited to, those including amides, sulfonamides, imides, imines, O-acyl oximes, benzoyloxycarbonyl derivatives, quarternary ammonium salts, and nifedipines, examples of which may include o-{(β-(dimethylamino)ethyl)aminocarbonyl}benzoic acid, o-{(γ-(dimethylamino)propyl)aminocarbonyl} benzoic acid, 2,5-bis{(β-(dimethylamino)ethyl)aminocarbonyl}terephthalic acid, 2,5-bis{(γ-(dimethylamino)propyl)aminocarbonyl}terephthalic acid, 2,4-bis{(β-(dimethylamino)ethyl) aminocarbonyl}isophthalic acid, and 2,4-bis{(γ-(dimethylamino)propyl)aminocarbonyl}isophthalic acid. Other examples include compounds that decompose and generate a base, such as triphenylmethanol, photoactive carbamates such as benzyl carbamate and benzoin carbamate; amides such as O-carbamoylhydroxylamide, O-carbamoyloxime, aromatic sulfonamide, alpha-lactam and N-(2-allylethynyl)amide, as well as other amides; oxime esters, α-aminoacetophenone, and cobalt complexes. Specific examples thereof include 2-nitrobenzylcyclohexyl carbamate, triphenylmethanol, o-carbamoylhydroxylamide, o-carbamoyloxime, [[(2,6-dinitrobenzyl)oxy] carbonyl]cyclo hexylamine, bis[[(2-nitrobenzyl)oxy]carbonyl]hexane 1,6-diamine, 4-(methylthiobenzoyl)-1-methyl-1-morpholinoethane, (4-morpholinobenzoyl)-1-benzyl-1-dimethylaminopropane, N-(2-nitro benzyloxycarbonyl)pyrrolidine, hexaaminecobalt(III)tris(triphenyl methylborate) and 2-benzyl-2-dimethylamino-1-(4-morpholinophenyl)-butanone.

3. Peroxides

Suitable peroxides for use in the metallic oxide formulations include, but are not limited to, inorganic peroxides such as hydrogen peroxide, metal peroxides (e.g., peroxides of group I or group II metals), organic peroxides such as benzoyl peroxide, 3,3′,4,4′-tetra(t-butylperoxycarbonyl)benzophenone, 3,3′,4,4′-tetra(t-amylperoxycarbonyl)benzophenone, 3,3′,4,4′-tetra(t-hexylperoxycarbonyl)benzophenone, 3,3′,4,4′-tetra(t-octylperoxycarbonyl)benzophenone, 3,3′,4,4′-tetra(t-cumylperoxycarbonyl)benzophenone, 3,3′,4,4′-tetra(t-isopropylcumylperoxycarbonyl)benzophenone and di-t-butyldiperoxyisophthalate, and peroxyacids such as peroxymonosulphuric acid and peroxydisulphuric acid, and combinations thereof.

B. Stabilizers

The metallic oxide formulations can include one or more stabilizer compounds. Suitable stabilizers include, but are not limited to, a lactone. In particular, suitable lactones include, but are not limited to, α-acetolactone, β-propiolactone, gamma-valerolactone, and gamma-butyrolactone. In addition, or alternatively, the stabilizer can be a carboxylic acid. Suitable carboxylic acids include, but are not limited to, acetic acid, propionic acid, and isobutyric acid. Those skilled in the art would appreciate that one or more additional stabilizers can be used in order to enhance other beneficial properties of the metallic oxide formulations and/or final layers prepared from the same.

Those skilled in the art will recognize that the amount of the stabilizer, like any of the other optional ingredients can be varied. In some embodiments, for example, the stabilizer is present in the metallic oxide formulations at no more than 20% by weight. In other embodiments, the stabilizer is present in the metallic oxide formulations at no more than 10% by weight. Those skilled in the art will further recognize that the above-described amounts of the stabilizer are not strictly bounded limits and include amounts of the stabilizer outside of these weight percentages. In some embodiments, for example, the stabilizer can be present in amounts exceeding the disclosed amount by 10%. Thus, an embodiment of the metallic oxide formulations including “no more than approximately 20% by weight” of the stabilizer can include 22% by weight of the stabilizer. Similarly, embodiment of the metallic oxide formulations including “no more than approximately 10% by weight of the stabilizer can include 11% by weight, of the stabilizer. In other embodiments, for example, the stabilizer can be present in amounts exceeding the disclosed amount by 5%. Thus, an embodiment of the metallic oxide formulations including “no more than approximately 20% by weight” of the stabilizer can include 21% by weight of the stabilizer. Similarly, an embodiment of the metallic oxide formulations including “no more than approximately 10% by weight” of the stabilizer can include 10.5% by weight of the stabilizer.

C. Crosslinkers

The metallic oxide formulations can also optionally contain various crosslinkers. Suitable crosslinkers include, for example, di-, tri-, tetra-, or higher multi-functional ethylenically unsaturated monomers. Crosslinkers useful in the present disclosure include, for example: trivinylbenzene, divinyltoluene; divinylpyridine, divinylnaphthalene, divinylxylene, ethyleneglycol diacrylate, trimethylolpropane triacrylate, diethyleneglycol divinyl ether, trivinylcyclohexane, allyl methacrylate (“ALMA”), ethyleneglycol dimethacrylate (“EGDMA”), diethyleneglycol dimethacrylate (“DEGDMA”), propyleneglycol dimethacrylate, propyleneglycol diacrylate, trimethylolpropane trimethacrylate (“TMPTMA”), divinyl benzene (“DVB”), glycidyl methacrylate, 2,2-dimethylpropane 1,3 diacrylate, 1,3-butylene glycol diacrylate, 1,3-butylene glycol dimethacrylate, 1,4-butanediol diacrylate, diethylene glycol diacrylate, diethylene glycol dimethacrylate, 1,6-hexanediol diacrylate, 1,6-hexanediol dimethacrylate, tripropylene glycol diacrylate, triethylene glycol dimethacrylate, tetraethylene glycol diacrylate, polyethylene glycol diacrylate, tetraethylene glycol dimethacrylate, polyethylene glycol dimethacrylate, ethoxylated bisphenol A diacrylate, ethoxylated bisphenol A dimethacrylate, polyethylene glycol dimethacrylate, poly(butanediol)diacrylate, pentaerythritol triacrylate, trimethylolpropane triethoxy triacrylate, glyceryl propoxy triacrylate, pentaerythritol tetraacrylate, pentaerythritol tetramethacrylate, dipentaerythritol monohydroxypentaacrylate, divinyl silane, trivinyl silane, dimethyl divinyl silane, divinyl methyl silane, methyl trivinyl silane, diphenyl divinyl silane, divinyl phenyl silane, trivinyl phenyl silane, divinyl methyl phenyl silane, tetravinyl silane, dimethyl vinyl disiloxane, poly(methyl vinyl siloxane), poly(vinyl hydro siloxane), poly(phenyl vinyl siloxane), tetra(C₁-C₈)alkoxyglycoluril such as tetramethoxyglycoluril and tetrabutoxyglycoluril, and combinations thereof. In particular embodiments, crosslinkers include, but are not limited to, glycouril, malemine, multiepoxy, multihydroxyl, multi carboxylic acid, and combinations thereof.

D. Photoacid Generators

The metallic oxide formulations can also optionally include a photoacid generator (PAG). Suitable photoacid generators include, for example, sulfide and onium type compounds. Photoacid generators include, but are not limited to, diphenyl iodide hexafluorophosphate, diphenyl iodide hexafluoroarsenate, diphenyl iodide hexafluoroantimonate, diphenyl p-methoxyphenyl triflate, diphenyl p-toluenyl triflate, diphenyl p-isobutylphenyl triflate, diphenyl p-tert-butylphenyl triflate, triphenylsulfonium hexafluororphosphate, triphenylsulfonium hexafluoroarsenate, triphenylsulfonium hexafluoroantimonate, triphenylsulfonium triflate, (4-tbutylphenyl)tetramethylenesulfonium (3-hydroxyadamantanyl ester)-tetrafluoro-butanesulfonate), (4-tbutylphenyl)tetramethylenesulfonium (adamantanyl ester)-tetrafluoro-butanesulfonate) and dibutylnaphthylsulfonium triflate.

E. Inorganic Polymers

The metallic oxide formulations can also optionally include one or more inorganic polymers. Suitable inorganic polymers include, but are not limited to, hydrogen silsesquioxane (HSSQ), methyl silsesquioxane (MSSQ), and combinations thereof.

F. Surfactants

The metallic oxide formulations can also optionally include one or more surfactants to improve application properties to a substrate. Suitable surfactants include, but are not limited to, polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl aryl ethers such as polyoxyethylene octyl phenyl ether and polyoxyethylene nonyl phenyl ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, a fluorosurfactant such as EFTOP® EF301, EF303, and EF352 (manufactured by Mitsubishi Materials Electronic Chemicals Co., Ltd.), MEGAFAC® F171, F173, R-30, R-30N, and R-40 (manufactured by DIC Corporation), Fluorad FC-430 and FC431 (manufactured by Sumitomo 3M, Ltd.), Asahi Guard® AG710, and Surflon S-382, SC101, SC102, SC103, SC104, SC105, and SC106 (manufactured by Asahi Glass Co., Ltd.), and organosiloxane polymer KP341 (manufactured by Shin-Etsu Chemical Co., Ltd.).

G. Anti-Foam Agents

The metallic oxide formulations can also optionally include one or more anti-foam agents. Suitable anti-foam agents include, but are not limited to, polysiloxanes, petroleum hydrocarbons, acetylenics, vinyl polymers and polyalkoxylates.

H. Thixotropic Agents

The metallic oxide formulations can also optionally include one or more thixotropic agents. Suitable thixotropic agents include, but are not limited to, anhydrous silica and colloidal silica. The anhydrous silica can have, for example, silanol groups on the surface thereof in the form of fine powder (average particle size: about 1 to about 50 μm).

Processing the Metallic Oxide Formulations

The total solids content of the metallic oxide formulations is adjusted to between approximately 2% by weight and approximately 30% by weight. In some embodiments, the total solids content is adjusted to approximately 5% by weight to approximately 20% by weight before being applied to a wafer/substrate.

Those skilled in the art will further recognize that metallic oxide formulations having a total solids content of between “approximately 2% by weight and approximately 30% by weight” is not a strictly bounded range and can include total solids contents somewhat outside of this range. In one embodiment, for example, metallic oxide formulations having a total solids content of between “approximately 2% by weight and approximately 30% by weight” can include ±10% of the total solids content. Thus, an embodiment of the metallic oxide formulations having a total solids content of between “approximately 2% by weight and approximately 30% by weight” can have a total solids content ranging from 1.8% by weight to 33% by weight as well as all weight percentages falling within that range. In another embodiment, for example, metallic oxide formulations having a total solids content of between “approximately 2% by weight and approximately 30% by weight” can include ±5% of the total solids content. Thus, an embodiment of the metallic oxide formulations having a total solids content of between “approximately 2% by weight and approximately 30% by weight” can have a total solids content ranging from 1.9% by weight to 31.5% by weight as well as all weight percentages falling within that range.

Suitable wafer/substrate materials include, but are not limited to, low dielectric constant materials, silicon, silicon substrates coated with a metal surface, copper coated silicon wafers, copper, aluminum, polymeric resins, silicon dioxide, metals, doped silicon dioxide, silicon nitride, tantalum, polysilicon, ceramics, aluminum/copper mixtures, any of the metal nitrides such as AlN, gallium arsenide and other Group III/V compounds. The wafer/substrate may also contain antireflective coatings or underlayers, such as high carbon underlayers coated over the above-mentioned substrates. Further, the wafer/substrate may include any number of layers made from the materials described above.

Once applied on a wafer/substrate, the metallic oxide formulations are baked at a temperature(s) between approximately 90° C. to approximately 250° C. for approximately 60 seconds. In some embodiments, for example, the metallic oxide formulations are baked at a temperature(s) between approximately 110° C. to approximately 180° C. for approximately 60 seconds.

Utilizing the above adjusted solids content and baking conditions, the resulting layer will generally be targeted to have a thickness of approximately 130 nm to approximately 150 nm and contain approximately 20% % by weight to approximately 60% by weight of metal oxide. In some embodiments, for example, the layer will be approximately 150 nm thick and contain approximately 30% by weight of metal oxide. Those skilled in the art will recognize that layers having thicknesses outside of this range can be prepared and that such layers fall within the disclosed and claimed subject matter.

Image Reversal

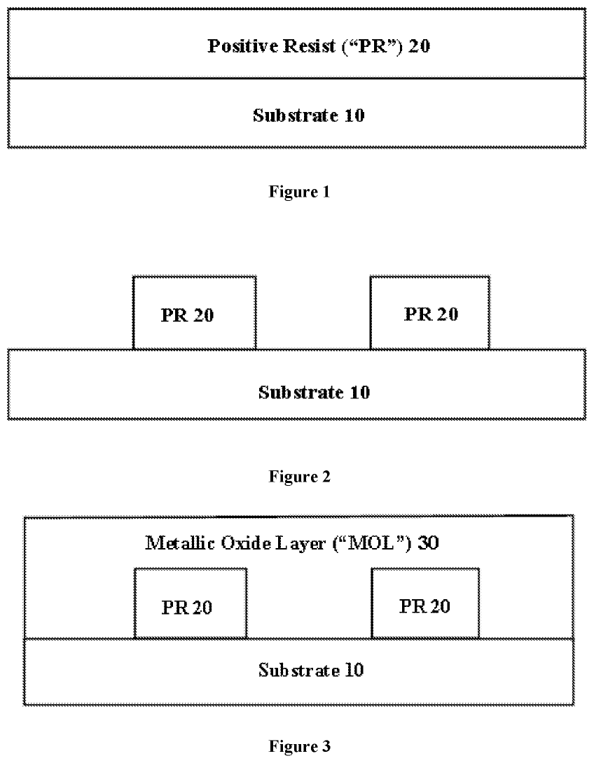

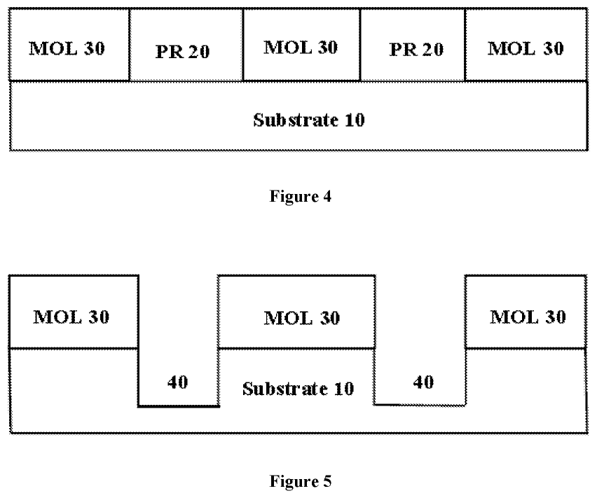

Films made from the metallic oxide formulations are particularly suited for performing image reversal (a.k.a. reverse tone imaging). The use of the metallic oxide formulations in such a process are illustrated in FIGS. 1-5. In FIG. 1, a photoresist material (“PR’) 20 is disposed on a surface of a substrate 10 (or can be disposed on an intervening undercoating layer (not shown) previously disposed on substrate 10). In one embodiment, photoresist 20 is a positive photoresist. In another embodiment, photoresist 20 is a negative photoresist. As shown in FIG. 2, photoresist 20 is used to form a photoresist pattern on substrate 10 (e.g., by way of being UV exposed (with desired masking) and developed). Thereafter, the photoresist 20 can be optionally baked to induce crosslinking (i.e., “freezing” the resist). In FIG. 3, photoresist 20 and substrate 10 are overcoated with the metallic oxide formulation disclosed herein to form metallic oxide layer (“MOL”) 30. As shown in FIG. 4, an upper surface of the photoresist 20 is then revealed by removing a portion of the overcoated metal oxide layer (i.e., the portion extending above photoresist 20) of metallic oxide layer 30 by way of chemical etching, dry/plasma etching (e.g., with SF₆, O₂, CF₄, CHF₃, Cl₂, HBr, SO₂, CO, etc. gases) or mechanical polishing to reduce the metallic oxide layer to a thickness approximately equal to the thickness of photoresist 20. In FIG. 5, a reverse tone pattern is formed by way of a further etching (e.g., by plasma etching or other known etching techniques) to remove photoresist 20 thereby leaving trench 40 in substrate 10. Thereafter, metallic oxide layer 30 can be used as a hardmask for further pattern transfer or removed.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

Materials and Methods:

Zirconium(IV) oxynitrate hydrate having the formula ZrO(NO₃)₂.xH₂O (x˜6) (a.k.a. zirconyl nitrate hydrate; CAS 14985-18-3) was obtained from Sigma-Aldrich.

Triton™ X100 (a.k.a. 4-(1,1,3,3-Tetramethylbutyl)phenyl-polyethylene glycol, t-octylphenoxypolyethoxyethanol, polyethylene glycol tert-octylphenyl ether; CAS 9002-93-1) was obtained from Sigma-Aldrich.

Polyvinylpyrridone was obtained from BASF.

AZ® 2110P is a 193 nm photoresist obtained from EMD Performance Materials.

### Formulation and Coating Example 1 (“Formulation 1”)

A solution of 18% by weight of (i) zirconium(IV) oxynitrate hydrate, (ii) 2% by weight of polyvinylpyrridone and (iii) 1,000 ppm of Triton™ X100 was prepared in water by mixing. The solution was filtered and spin-coated on a silicon wafer. The wafer was then baked at 250° C. for 60 seconds and aged for 1 week at 40° C. The coating quality and film thickness following baking at 250° C. for 60 seconds did not show changes by XSEM analysis.

### Formulation and Coating Example 2 (“Formulation 2”)

A solution of 18% by weight of (i) zirconium(IV) oxynitrate hydrate, (ii) 2% by weight of polyvinylpyrridone and (iii) 500 ppm of Triton™ X100 was prepared in water by mixing. The solution was filtered and spin-coated on a silicon wafer. The wafer was then baked at 250° C. for 60 seconds and aged for 1 week at 40° C. The coating quality and film thickness following baking at 250° C. for 60 seconds did not show changes by XSEM analysis.

### Resist-Pattern Filling Performance Evaluation Example 1

The solid content of Formulation 1 was adjusted to target a final film thickness of 150 nm from a 60-seconds bake at 120° C. The adjusted Formulation 1 was then spin-coated on a patterned AZ®2110P resist on silicon wafer with trench size of 100 nm (depth)×90 nm (width) and line/space (L/S) 1:1 at a spin speed of 1,500 rpm. The coated wafer was subsequently baked at 120° C. for 60 seconds. The XSEM data showed excellent film coating quality and good filling performances.

### Resist-Pattern Filling Performance Evaluation Example 2

The solid content of Formulation 2 was adjusted to target a final film thickness of 150 nm from a 60-second bake at 120° C. The adjusted Formulation 2 was then spin-coated on a patterned AZ® 2110P resist on silicon wafer with trench size of 100 nm (depth)×90 nm (width) and line/space (L/S) 1:1 at a spin speed of 1,500 rpm. The coated wafer was subsequently baked at 120° C. for 60 seconds. The XSEM data showed excellent film coating quality and good filling performances.

### Comparative Pattern Filling Example 1

A solution of 20% by weight of (i) zirconium(IV) oxynitrate hydrate and (ii) 1,000 ppm of Triton™ X100 was prepared in water by mixing followed by filtering. The solid content of the solution was adjusted to target a final film thickness of 150 nm from a 60-second bake at 120° C. The solution then was spin-coated on a patterned AZ® 2110P resist on silicon wafer with trench size of 100 nm (depth)×15 nm (width) and line/space (L/S) 1:1 at a spin speed of 1,500 rpm. The coated wafer was subsequently baked at 120° C. for 60 seconds. The XSEM data showed poor coating quality.

### Reversed Image Formation Example 1

The wafers on which Formulation 1 and Formulation 2 were evaluated for resist-pattern filling performance were respectively etched with SF₆ gas for approximately 20 seconds to remove the ZrOx overcoats on the resist patterns by means of an ICP etcher (LAM kiyo CX at IMEC). The wafers were then further etched using a center etch condition of 5 mT/Power 400 W/Bias 200V/2902 (sccm)/160Ar (sccm)/40 deg. As a result, the resist material was removed completely leaving the ZrOx pattern as a reversed tone image with a L/S 90 nm 1:1 on the wafers.

Analysis

Films/layers formed from the disclosed metallic oxide formulations have high metal oxide content (>40% by weight) while also having a very low organic component. It is known, for example, that ZrOx hard mask are generally known to exhibit excellent etch resistance in CF₄ and O₂ gases. The etch resistance of ZrOx is normally higher than that of TiOₓ and WOₓ of similar or higher metal content. Accordingly, ZrOx hard masks are often deemed to be advantageous over both silicon-based hardmasks as well as TiOₓ/WOₓ hardmasks.

In comparison, the disclosed high-metal content metallic oxide formulations, including those containing ZrOx, demonstrate much better etch selectivity to many substrates, such as Si and SiOₓ, with CF₄ or O₂ gases than previously reported compositions. With respect to known, ZrOx hard masks, the metallic oxide formulations disclosed and claimed herein—including those containing ZrOₓ—have significantly higher metal content. In particular, known ZrOx hard masks normally contain on the order of 25% to 40% by weight of metal in filling applications. In contrast, the metal content of the disclosed metallic oxide formulations exceeds 40% by weight. As such, layers prepared (e.g., in an imager reversal process) using the disclosed and claimed metallic oxide formulations, including those containing ZrOx, can be much thinner and can also be used as a hardmask for further pattern transfer.

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

1. A process for reverse tone imaging comprising the steps of:
(i) disposing a photoresist material on a surface substrate;
(ii) forming a photoresist pattern on the substrate;
(iii) optionally baking the photoresist pattern to induce crosslinking;
(iv) overcoating the photoresist pattern and substrate with a metallic oxide formulation comprising (a) one or more metal salts, (b) an organic polymer and (c) one or more solvents to form a metal oxide layer;
(v) revealing an upper surface of the photoresist pattern by removing at least a portion of the overcoated metal oxide layer; and
(vi) removing the photoresist pattern.

2. The process of claim 1, wherein the removing of the metal oxide layer comprises one or more of a chemical etching process, a plasma etching process and a mechanical polishing process.

3. The process of claim 1, wherein the one or more metal salts of the metallic oxide formulation includes one or more of Ti(IV), Zr(IV), Hf(IV), Mo(VI), Sn(IV), AI(III), In(III), Ga(III) and Zn(II).

4. The process of claim 1, wherein the one or more metal salts of the metallic oxide formulation includes Zr(IV).

5. The process of claim 1, wherein the metal salt includes one or more of a nitrate, a sulfate, an acetate, a fluorinated alkylacetate, a fluorinated alkysulfonate and a (meth)acrylate as a counterion.

6. The process of claim 1, wherein the one or more metal salts of the metallic oxide formulation includes one or more of zirconyl nitrate, aluminum nitrate, zirconyl methacylate, aluminum sulfate, titanium oxysulfate, aluminum trifluoroacetate and aluminum trifluorosulfonate.

7. The process of claim 1, wherein the organic polymer of the metallic oxide formulation includes one or more of polyvinylalcohol, polyvinylpyrridone, polyethyleneglycol, polypropyleneglycol, polyesters, polyacrylics, polymethacrylates, novolac resin, organosilsesquioxanes.

8. The process of claim 1, wherein an amount of the organic polymer in the metallic oxide formulation does not exceed 40% by weight.

9. The process of claim 1, wherein an amount of the organic polymer in the metallic oxide formulation does not exceed 20% by weight.

10. The process of claim 1, wherein the solvent of the metallic oxide formulation is an organic solvent, an aqueous solvent or a combination thereof.

11. The process of claim 1, wherein the solvent of the metallic oxide formulation is one or more of water, an alcohol, an ester, an ether, an alkylcarboxylic acid, a ketone, a lactone, a diketone, or a combination thereof.

12. The process of claim 1, wherein the solvent the metallic oxide formulation includes one or more of ethylene glycol monoalkyl ethers, diethylene glycol dialkyl ethers, propylene glycol monoalkyl ethers, propylene glycol dialkyl ethers, acetate esters, hydroxyacetate esters, lactate esters, ethylene glycol monoalkylether acetates, propylene glycol monoalkylether acetates, alkoxyacetate esters, cyclic ketones, non-cyclic ketones, acetoacetate esters, pyruvate esters, propionate esters, cyclohexanone, a propylene glycol monomethyl ether acetate (PGMEA), propylene glycol monomethyl ether (PGME), benzylethyl ether, dihexyl ether, diethylene glycol monomethyl ether, diethylene glycol monoethyl ether, acetonylacetone, caproic acid, capric acid, 1-octanol, 1-nonanol, benzyl alcohol, benzyl acetate, ethyl benzoate, diethyl oxalate, diethyl maleate, γ-butyrolactone, ethylene carbonate, propylene carbonate and phenylcellosolve acetate.

13. The process of claim 1, wherein the metallic oxide formulation further optionally comprises one or more of a catalyst, a crosslinker, a photoacid generator, an organic polymer, an inorganic polymer, a surfactant, a wetting agent, an anti-foam agent, a thixotropic agent, a pre-solvent and combinations thereof.

14. The process of claim 1, wherein the metallic oxide formulation has an organic content that is no more than approximately 20% by weight.

15. The process of claim 1, wherein the metallic oxide formulation has an organic content that is no more than approximately 10% by weight.

16. The process of claim 1, wherein the metallic oxide formulation has an organic content that is no more than approximately 5% by weight.

17. The process of claim 1, wherein the metallic oxide formulation has a total solids content ranging from 2% by weight and approximately 30% by weight.

18. The process of claim 1, wherein the metallic oxide formulation has a total solids content ranging from 5% by weight and approximately 20% by weight.

19. The process of claim 1, wherein the metallic oxide layer has a metal oxide content of between approximately 20% by weight to approximately 60% by weight.

20. The process of claim 1, wherein the metallic oxide layer has a metal oxide content of between approximately 30% by weight to approximately 50% by weight.

21. The process of claim 1, wherein the photoresist material comprises a positive photoresist.

22. The process of claim 1, wherein the photoresist material comprises a negative photoresist.

23. The process of claim 1, wherein the metallic oxide formulation comprises one or more compositions disclosed or claimed in U.S. Pat. No. 10,241,409.
